(19) United States
(12) Patent Application Publication
(10) Pub. No.: US 2026/0262474 A1
(43) Pub. Date: Sep. 3, 2026

(54) STACKED SUBSTRATE PACKAGE ASSEMBLY METHODS USING RIGID CARRIERS

(71) Applicant: MARVELL ASIA PTE LTD, Singapore (SG)

(72) Inventors: Richard Graf, Gray, ME (US); Luke England, Lakeway, TX (US); Manish Nayini, Wappingers Falls, NY (US); Janak G. Patel, South Burlington, VT (US)

(21) Appl. No.: 19/654,656

(22) Filed: Apr. 22, 2026

Related U.S. Application Data
(63) Continuation-in-part of application No. 19/549,220, filed on Feb. 25, 2026.
Application No. 19/549,220 is a continuation of application No. 17/652,542, filed on Feb. 25, 2022, now Pat. No. 12,588,470.
(60) Provisional application No. 63/153,836, filed on Feb. 25, 2021.

(51) Int. Cl. H10P 72/70; H10W 70/685; H10W 72/00; H10W 72/20; H10W 72/30; H10W 90/00; H10W 74/15

(52) U.S. Cl. CPC H10P 72/74; H10W 70/685; H10W 72/072; H10W 72/20; H10W 72/30; H10W 72/851; H10W 90/401; H10W 90/701; H10W 74/15; H10W 90/724; H10W 90/734

(57) ABSTRACT

A method for assembling and mounting a stacked substrate package includes: a) mounting a build-up substrate to a base substrate, the build-up substrate including interconnections between surfaces of the build-up substrate, and the base substrate including interconnections between surfaces of the base substrate; b) mounting the base substrate to a rigid carrier; and c) mounting an integrated circuit to the build-up substrate, where, during a), b), and c), the build-up substrate, the base substrate and the integrated circuit are stacked to provide a substrate stack, where i) a) is performed before at least one of b) and c), ii) c) is performed before at least one of a) and b), or iii) b) is performed before a) and c), and c) is performed before a).

### CROSS-REFERENCE TO RELATED APPLICATIONS

The present disclosure is a continuation-in-part of United States Patent Application No. 19/549,220 filed on February 25, 2026. United States Patent Application No. 19/549,220 is a continuation of United States Application No. 17/652,542, filed February 25, 2022, which claims the benefit of United States Provisional Patent Application No. 63/153,836, filed February 25, 2021. The entire disclosures of the applications referenced above are incorporated herein by reference.

### FIELD

This disclosure relates to the assembly of stacked substrate packages. More particularly, this disclosure relates to assembly of a stacked substrate package in a manner that avoids warping of substrate layers, which may cause misalignment of surface-mounted contacts between layers.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

A stacked substrate package includes multiple layers of substrates bearing circuitry and having contacts that must align for proper conductivity. However, when these layers of substrates are joined together, warping may result in misalignment of the contacts, resulting in a non-functional device. For example, in a single chip stacked package configuration, a single integrated circuit die will be mounted to a build-up substrate, which itself is mounted to a base substrate. Starting from the base substrate the pitch -- i.e., the distance between surface contacts or pins – decreases with each additional top mounted layer. An interface between the integrated circuit die and build-up substrate is prone to warping which can cause electrical misconnections between the integrated circuit die and the build-up substrate. An interface between the build-up substrate and the base substrate is also susceptible to warping during assembly. As such when a stacked substrate package is assembled, bonding and electrically coupling the integrated circuit die to the build-up substrate and/or bonding and electrically coupling the build-up substrate to the base substrate can cause warping and/or bending.

### SUMMARY

A method for assembling and mounting a stacked substrate package is disclosed. The method includes: a) mounting a build-up substrate to a base substrate, the build-up substrate including interconnections between surfaces of the build-up substrate, and the base substrate including interconnections between surfaces of the base substrate; b) mounting the base substrate to a rigid carrier; and c) mounting an integrated circuit to the build-up substrate, where, during a), b), and c), the build-up substrate, the base substrate and the integrated circuit are stacked to provide a substrate stack, where i) a) is performed before at least one of b) and c), ii) c) is performed before at least one of a) and b), or iii) b) is performed before a) and c), and c) is performed before a).

In other features, a) is performed before b). In other features, a) is performed before c). In other features, a) is performed before b) and c). In other features, a) and c) are performed concurrently. In other features, c) is performed before a). In other features, c) is performed before b). In other features, c) is performed before a) and b). In other features, d) is performed after at least one of a), b) and c).

In other features, the method further includes d) binding layers of the base substrate together, where d) is performed before at least one of a), b), and c). In other features, d) is performed before a) and c).

In other features, the method further includes mounting a lid over the integrated circuit and to the base substrate. In other features, the rigid carrier has a same coefficient of thermal expansion as the base substrate.

In other features, first contacts electrically connect the integrated circuit to the build-up substrate and second contacts electrically connect the build-up substrate to the base substrate.

In other features, the method further includes underfilling space between the integrated circuit and the build-up substrate and space between the build-up substrate and the base substrate with bonding material.

In other features, the space between the integrated circuit and the build-up substrate and the space between the build-up substrate and the base substrate are underfilled subsequent to performing a), b), and c).

In other features, the first contacts and the second contacts are implemented as at least one of i) a ball grid array, ii) controlled collapse of chip connections, iii) micro-bumps, iv) copper pillar connections, v) a land grid array, vi) a pin grid array.

In other features, the method further includes: d) releasing the substrate stack from the rigid carrier; and subsequent to d), forming contacts on one of the surfaces of the base substrate and mounting the base substrate to a board such that the contacts electrically connect the base substrate to the board. In other features, the base substrate is adhered to the rigid carrier.

In other features, the method further includes d) releasing the substrate stack from the rigid carrier, where d) includes treating an adhesive that adheres the base substrate to the rigid carrier with a solvent to weaken the adhesive and physically separate the base substrate from the rigid carrier.

In other features, the method further includes: disposing a fixture on the rigid carrier, the fixture configured to surround the base substrate and including first pins extending perpendicular to a top surface of the fixture; and releasing the substrate stack from the rigid carrier including positioning a torque rod between the first pins and applying torque on the fixture via the first pins relative to the rigid carrier to release the base substrate from the rigid carrier.

In other features, a method for assembling and mounting a stacked substrate package is provided. The method includes: a) mounting a build-up substrate to a base substrate, the build-up substrate including interconnections between surfaces of the build-up substrate, and the base substrate including interconnections between surfaces of the base substrate; b) mounting the base substrate to a rigid carrier; and c) mounting an integrated circuit to the build-up substrate. During a), b), and c), the build-up substrate, the base substrate and the integrated circuit are stacked to provide a substrate stack. Either i) c) is performed before at least one of a) and b), or ii) b) is performed before a) and c), and c) is performed before a). In other features, the method further includes releasing the substrate stack from the rigid carrier.

A method according to implementations of the subject matter of this disclosure, for assembling at least one stacked substrate package, includes binding a laminated base substrate, configured to route interconnections between circuitry on a first surface of the laminated base substrate and circuitry on a second surface of the laminated base substrate, to a surface of a rigid carrier to prevent warping of the laminated base substrate, coupling at least one dielectric build-up substrate, separate from the laminated base substrate to form a substrate stack, the at least one dielectric build-up substrate configured to route integrated interconnections between a top surface and a bottom surface of the dielectric build-up substrate, to the laminated base substrate, to each respective one of the at least one base substrate, coupling at least one integrated circuit die to the at least one dielectric build-up substrate, and releasing the rigid carrier from the laminated base substrate after coupling the at least one integrated circuit die to the at least one dielectric build-up substrate.

In a first implementation of such a method, selecting as the rigid carrier material a material that prevents warping during assembly of the stacked substrate package.

In a second implementation of such a method may further include binding the laminated base substrate may include binding at least one laminated base substrate to the surface of the rigid carrier to prevent warping of the at least one laminated base substrate.

A first aspect of that second implementation, where at least one of (a) a first interface, between a surface of one of the at least one laminated base substrate and a surface of one of the at least one dielectric build-up substrate, or (b) a second interface, between a surface of one of the at least one dielectric build-up substrate and a surface of an integrated circuit die, includes a respective one of (1) a ball grid array (BGA) on each surface of the at least one of the first interface and the second interface, (2) controlled collapse of chip connections (C4) on each surface of the at least one of the first interface and the second interface, (3) micro-bumps on each surface of the at least one of the first interface and the second interface, (4) copper pillar connections on each surface of the at least one of the first interface and the second interface, (5) a land grid array (LGA) on each surface of the at least one of the first interface and the second interface, or (6) a pin grid array (PGA) on each surface of the at least one of the first interface and the second interface.

A second aspect of that second implementation, where binding the at least one laminated base substrate to the rigid carrier includes adhering the carrier to the at least one laminated base substrate.

In a first instance of that second aspect, where adhering the at least one laminated base substrate to the rigid carrier includes adhering with an adhesive material.

In a second instance of that second aspect, where adhering the at least one laminated base substrate to the rigid carrier includes adhering with an organic bonding material.

In a first variant of that second instance, where adhering with the organic bonding material includes adhering with one of (a) WaferBOND® HT-10.11, (b) WaferBOND® HT-10.12, or (c) BrewerBOND® 305, available from Brewer Science, Inc.

In a third implementation of such a method, where the laminated base substrate has a first coefficient of thermal expansion and includes binding the rigid carrier to the at least one laminated base substrate includes selecting the carrier to have a second coefficient of thermal expansion substantially equal to the first coefficient of thermal expansion.

In a third instance of that second aspect, where releasing the rigid carrier from the laminated base substrate includes treating the adhesive that adheres the laminated base substrate and the rigid carrier with a solvent that weakens the adhesive and physically separating the laminated base substrate and the rigid carrier that have been treated with the solvent.

In a first variant of that third instance, where treating the adhesive that adheres the laminated base substrate and the rigid carrier with a solvent includes immersing the rigid carrier and the base substrate, while bound together, in a solvent bath for a predetermined period of time.

In a fourth implementation of such a method, where releasing the rigid carrier from the substrate stack may include separating the laminated base substrate from the rigid carrier by applying torque to the stacked substrate package about an axis normal to the surface of the rigid carrier.

In a fifth implementation of such a method, where releasing the rigid carrier from the substrate stack may include heating the laminated base substrate to weaken adhesion of the rigid carrier to the laminated base substrate and after weakening the adhesion, separating the rigid carrier from the laminated base substrate with an in-plane force that translates the rigid carrier in parallel to the laminated base substrate.

In a sixth implementation of such a method, where releasing the rigid carrier from the substrate stack may include exposing the adhesive to a laser source to weaken the adhesive and after weakening the adhesive, separating the rigid carrier from the laminated base substrate.

In a seventh implementation of such a method, where releasing the rigid carrier from the substrate stack may include chilling the substrate stack to weaken adhesion of the rigid carrier to the laminated base substrate and after weakening the adhesion, separating the rigid carrier from the laminated base substrate with an in-plane force that translates the rigid carrier in parallel to the laminated base substrate.

In an eighth implementation of such a method, where the assembling of the at least one stacked substrate package further includes forming, concurrently, substrate stacks on a rigid carrier and releasing each of the substrate stacks, each of which are assembled to be stacked substrate packages.

In a ninth implementation of such a method, where the assembling of the at least one stacked substrate package further may include applying a Thermal Interface Material (TIM) on the top surface of the integrated circuit die.

A first aspect of that ninth implementation, where the assembling of the at least one stacked substrate package may further include enclosing the integrated circuit die with a lid that is in thermal contact with the Thermal Interface Material.

A stacked substrate package formed by a method according to implementations of the subject matter of this disclosure, including binding a laminated base substrate, configured to route wires between a top surface and a bottom surface-mount package of the laminated base substrate, to a surface of a rigid carrier to prevent warping during assembly, coupling at least one dielectric build-up substrate, separate from the at least one laminated base substrate to form a substrate stack, the at least one dielectric build-up substrate configured to route wires between a top surface and a bottom surface mount package of the dielectric build-up substrate, to each respective one of the at least one laminated base substrate, coupling at least one integrated circuit die, having a bottom surface mount package, to each of the at least one dielectric build-up substrate and removing the rigid carrier from each respective one of the at least one stacked substrate package after coupling the at least one integrated circuit die.

In a first implementation of such a stacked substrate package formed by such a method, where the rigid carrier includes a material that prevents warping during assembly of the stacked substrate package.

In a second implementation of such a stacked substrate package formed by such a method, where binding the laminated base substrate may further include binding at least one laminated base substrate to the surface of the rigid carrier to prevent warping of the at least one laminated base substrate.

In a third implementation of such a stacked substrate package formed by such a method, where the laminated base substrate has a first coefficient of thermal expansion and the rigid carrier material has a second coefficient of thermal expansion substantially equal to the first coefficient of thermal expansion.

A first aspect of that third implementation, where the rigid carrier material includes glass.

In a fourth implementation of such a stacked substrate package formed by such a method, where the at least one laminated base substrate is bound to the rigid carrier with an adhesive material.

An apparatus according to implementations of the subject matter of this disclosure, for releasing a stacked substrate package from a rigid carrier to which the stacked substrate package is adhered, the apparatus including a base having a major plane, two secure pins, each of the secure pins having a longitudinal axis extending, in a first direction perpendicular to the major plane of the base, from a surface of the base parallel to the major plane of the base, a frame-shaped torque fixture having a major plane, the fixture being configured to surround the perimeter of the stacked substrate package and to rest on the surface of the base during a release operation, two torque lever pins, each of the torque lever pins having a longitudinal axis extending from the frame-shaped torque fixture perpendicular to the major plane of the torque fixture, in the first direction when the torque fixture is resting on the surface of the base, and a torque rod positioned between the two torque lever pins, the torque rod being configured to engage the torque lever pins to apply a torque to the frame-shaped fixture.

In a first implementation of such an apparatus, where the two secure pins are configured to engage two matching holes in the rigid carrier to prevent movement of the rigid carrier in a plane parallel to the major plane of the base.

In a second implementation of such an apparatus, where the frame-shaped torque fixture is configured to be placed onto the rigid carrier, such that the major plane of the torque fixture is parallel to the major plane of the base.

In a second implementation of such an apparatus, where the torque rod is configured to engage the two torque lever pins to apply to the torque fixture a torque about an axis perpendicular to the major plane, the torque fixture transferring the torque to the substrate relative to the rigid carrier.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF DRAWINGS

Further features of the disclosure, its nature, and various advantages, will be apparent upon consideration of the following detailed description, taken in conjunction with the accompanying drawings, in which like reference characters refer to like parts throughout, and in which:

FIG. 1 is a cross-sectional view of a substrate stack mounted on top of a carrier in accordance with implementations of the subject matter of this disclosure;

FIG. 2 is an assembly diagram illustrating a progression of stages of the assembly of a stacked substrate package according to some implementations of the subject matter of this disclosure;

FIG. 3 is an assembly diagram illustrating a progression of stages of the assembly of a stacked substrate package according to another implementation of the subject matter of this disclosure;

FIG. 4 is a cross-sectional view of a stacked substrate package with a ball grid array mounted on a circuit board according to some implementations of the subject matter of this disclosure;

FIG. 5 is a cross-sectional view of a plurality of substrate stacks mounted on top of a carrier in accordance with some implementations of the subject matter of this disclosure.

FIG. 6 is a top perspective view of an apparatus used to remove a stacked substrate package from a carrier using mechanical torque in accordance with some implementations of the subject matter of this disclosure;

FIG. 7 is a flow diagram illustrating an example assembly process for a stacked substrate package according to some implementations of the subject matter of this disclosure;

FIG. 8 is a flow diagram illustrating a method of selecting materials to bind the base substrate to the carrier according to some implementations of the subject manner of this disclosure;

FIG. 9 is an assembly diagram illustrating a progression of stages of the assembly of a stacked substrate package according to some implementations of the subject matter of this disclosure; and

FIG. 10 is a flow diagram illustrating another example assembly process for a stacked substrate package according to some implementations of the subject matter of this disclosure.

### DESCRIPTION

Various multi-layer package substrates, ball grid arrays (BGAs), land grid arrays (LGAs), and pin grid arrays (PGAs), include a plurality of bonded together layers. These types of multi-layer package substrates are prevalent in electronic circuit fabrication for packaging integrated circuits and other electronic devices. A multi-layer package substate may include a build-up substrate and a base substrate. The purpose of the base substrate is to provide a larger fan-out from the build-up substrate. In some implementations of the present disclosure, the base substrate may be formed of a plurality of laminated dielectric layers. An example of a base substrate is a high-density interconnect (HDI) substrate, which includes multi-layer, high-density circuits with fine line routing. The build-up substrate, when electrically coupled to an integrated circuit (IC) die, provides a layer where complex circuits may reside. This increases the number of routing options for the IC die, and for high-performance routing between multiple IC dies that are mounted onto the same build-up substrate. The build-up substrate may function as a non-silicon interposer in some implementations of the present disclosure. The interposer may allow for multiple IC dies to be mounted and electrically coupled onto the interposer. The interposer increases the fan-out from the IC dies and allows for high-performance routing networks to be implemented between the IC dies. An example of a build-up substrate that may be used is an Ajinomoto build-up film (ABF)™ substrate, which is often used for high-performance IC dies.

The bonding of layers during assembly of a stacked substrate package is meant to couple and join an IC die and the substrate layers together such that good connections between surface-mounted contacts on adjacent surfaces of the layers is ensured. The surface-mounted contacts are used to make electrical connections between circuits on adjacent layers and need to be well aligned. A typical technique for fabricating stacked substrate packages is to build up substrate layers in a stacked manner, one layer at a time from bottom to top, to form a stacked multi-layer substrate package. However, in some cases the stacking of substrate layers to fabricate a package may lead to warping or bending of the component substrate layers. This can occur due to heat applied when bonding and electrically coupling layers in a substrate stack. Warping and/or bending may occur between the base substrate and a build-up substrate or between the build-up substrate and the IC die that is mounted on top of the base substrate.

In many implementations, the substrate layers of the stacked substrate package are bound by depositing an underfill material between two layers and allowing a predetermined amount of time for the underfill material to cure, thereby bonding the layers together. The specific process of bonding and electrically coupling the stacked substrate package layers may vary based on the material composition of the two layers, the composition of the underfill material used, the distribution of the underfill material, the sizes of substrates, and various other environmental considerations. Although the assembly of these packages may be performed in a controlled environment to mitigate inconsistencies that lead to a drop in yield of production, warping of the substrate layers may still occur. Warping of the base substrate or the build-up substrate may make the mounting of other components more difficult and result in poor connections between surface-mounted contacts on adjacent layers.

In order to reduce such warping, in accordance with implementations of the subject matter of this disclosure, a temporary rigid carrier may be included in the substrate stack during assembly. The carrier should be rigid to resist deformation by mechanical forces as well as be unsusceptible to deformation that might otherwise result from large temperature variations (e.g., in a range from about 20°C to about 260°C) that may occur during reflow processes to bind and/or electrically couple the interconnects as a part of the stacked substrate package assembly process. The carrier should also be capable of being removed without deformation of the stacked substrate package, which, if it occurs, would negate the benefit of using the carrier during the package assembly. In some implementations, the rigid carrier may have a coefficient of thermal expansion (CTE) that is substantially equal to that of the base substrate, which is to be mounted on top of the carrier. A closely matched CTE between the base substrate and the carrier ensures, when the base substrate is adhered to the carrier, that the base substrate and the carrier expand and contract similarly as the reflow temperature varies, which minimizes warping during further assembly operations.

For example, the carrier material, whether glass or some other material, should have a CTE in the range of between 6 ppm/°C and 12 ppm/°C depending on the CTE of the base substrate material. For base substrate materials that have a CTE close to 12 ppm/°C, an alkali-containing glass carrier may have an appropriately matched CTE. For a base substrate material with a lower CTE, a non-alkali glass can be used as the carrier material. Although various types of glass may be used as the carrier material, any rigid material that is resistant to warping and that has an appropriate CTE may be used. Some alternative carrier materials may be used including, but are not limited to, silicon, ceramic, and metals such asstainless steel, aluminum, and titanium.

The order of assembly of the layers can have an impact on warping, as well as overall yield of production. For this reasons, in a first example implementation of the subject matter of this disclosure, the build-up substrate is mounted on a rigid surface created by adhering the base substrate to the rigid carrier and the IC die is then mounted on the build-up substrate.

In this implementation, the IC die is placed onto the build-up substrate and build-up substrate is placed onto the base substrate and surface-mounted contacts are coupled in reflow. The IC die-build-up substrate interface and the build-up substrate-base substrate interface are then underfilled, cured, and the respective layers are therefore bonded at the same time. The underfill material is applied between the IC die and the build-up substrate, and between the build-up substrate and the base substrate. In an example embodiment, the underfill material is an epoxy resin and/or an acrylic material that, when cured, protects the surface-mounted contacts between the layers. In an example implementation, all of the underfill material between layers is cured at the same time. The curing process is a chemical process in which the underfill material solidifies, forming a bond stronger than when the material was deposited. Curing of an epoxy resin may be a thermal process, in which the layers are exposed to a constant temperature for a period of time. Curing of an acrylic material may be a photosensitive process, in which the acrylic material is exposed to a light source with a specific wavelength to fully cure the material.

Warping can occur during a curing process, for example, between the build-up substrate and the base substrate and between the IC die and build-up substrate. In the foregoing example implementation, in which the bonds between all layers are cured at once, any such warping could result in loss of an entire substrate stack. Therefore, in a second example implementation of the subject matter of this disclosure, the base substrate is bonded onto the carrier, then the IC die is mounted on the build-up substrate, then lastly the build-up substrate is mounted on the base substrate. While warping may also occur in this second implementation, this implementation may be well-suited for larger IC dies or for IC dies that have small surface-mounted contact pitch. As dies become larger or the pitch gets smaller, the margin of error in the alignment of the contacts decreases. This second implementation, in which only the IC die and the build-up substrate are bonded and electrically coupled initially, allows more control of the alignment of contacts for good electrical connection between the IC die and build-up substrate as compared to the first implementation. However, there is a trade-off, in that in this second implementation, there may be a higher likelihood that the build-up substrate will warp because the build-up substrate is not supported by any other layer when the IC die is being mounted to the build-up substrate.

In another example implementation, the build-up substrate is initially mounted to the base substrate and then either i) the base substrate is mounted on the rigid carrier, or ii) the IC die is mounted on the build-up substrate. Warping may occur between the build-up substrate and the base substrate in this instance but not between the build-up substrate and the IC die. Initially attaching the build-up substrate to the base substrate reduces complexity of joining these substrate together due to their reduced size and allows less thermal mass during reflow.

After a substrate stack has been assembled, the rigid carrier is removed. Therefore, when the base substrate is mounted to the carrier, care should be taken to ensure that the adhesion between the carrier and the base substrate is not too strong that the base substrate cannot later be released from the carrier, while at the same time it should be strong enough to prevent warping of the substrate stack during assembly. There are several different release methods in accordance with implementations of the subject matter of this disclosure. In accordance with some implementations of the subject matter of this disclosure, the bonding material itself is releasable, while in other implementations, the bonding material incorporates, or is paired with, a release material that facilitates breaking of the bond to remove the rigid carrier from the substrate stack.

The techniques that may be used to release the carrier from the substrate stack may rely on mechanical shear force, mechanical torque, a chemical solvent, thermal treatment, or laser exposure. In some implementations, the carrier is removed not only without damaging the substrate stack, but also without damaging the carrier, so that the carrier may be reused during assembly of additional stacked substrate packages.

One method, according to implementations of the subject matter of this disclosure for release or removal of the carrier, is a mechanical shear method performed at room temperature. To facilitate this method, the bonding material used to adhere the base substrate to the carrier may be paired with a release material. This allows the two layers to physically separate from each other under shear forces without weakening the bond between the carrier and base substrate so much that the bond cannot prevent warping. While mechanical separation of the carrier can cause some stress on the substrate stack, this method does not require any heat or chemical treatment, which can increase the likelihood of the stacked package experiencing warping or having defects. Some characteristics of bonding materials that can be considered for this mechanical release method are i) thermal stability, which is the ability of the material to release without damaging the substrate package, and ii) the amount of material residue left on the surface of the base substrate after carrier removal. If any residue of the bonding material remains after carrier removal, the residue may interfere with contact between surface-mounted contacts on the underside of the base substrate and any printed circuit board to which the stacked substrate package may later be mounted.

In a still further implementation of the subject matter of this disclosure, mechanical torque may be applied to the substrate stack in order to remove it from the rigid carrier. In this case, a force is applied parallel to the plane of the base substrate to cause a torque about an axis perpendicular to that plane. Such an implementation may be carried out using a purpose-built apparatus that holds the carrier in place while applying the torque to the substrate stack via a frame. The frame is fitted around the substrate stack. This implementation may be further facilitated by bonding the base substrate to the carrier using a bonding material that is strong in a translational mode (whether parallel or perpendicular to the plane of the bond) but weaker in a torsional mode. This may be done such that the substrate stack is removed when desired while avoiding possible separation of layers of the substrate stack under normal conditions in which the application of torque is unlikely.

Another release method according to implementations of the subject matter of this disclosure is a chemical solvent release method. In this method, a solvent is used to chemically break down the bonding material, without affecting the remainder of the package or any circuits formed thereon. The solvent used in this process may include, but is not limited to, alcohols (e.g., methanol, ethanol, isopropanol, etc.) and inorganic acids (e.g., nitric acid and hydrochloric acid, etc.). In this method, the carrier may be perforated to allow the solvent to better penetrate the bonding material. The solvent may be applied by submerging the stacked package in the solvent for a predetermined amount of time, after which the bonding material will have broken down sufficiently to allow the carrier to be separated from the substrate stack without damaging the stack. The predetermined amount of time for the substrate stack to release from the carrier may range from 5 minutes to 90 minutes, depending on the solvent used, the solvent bath temperature, and the thickness of the applied bonding material.

Still another release method according to implementations of the subject matter of this disclosure is a temperature treatment method in which the substrate stack assembly, including the carrier, is heated until the bonding material between the carrier and base substrate weakens. After the bonding material has been weakened, the carrier may be translated relative to the substrate stack to remove the rigid carrier from the substrate stack. For implementations in which this heating treatment is used, a bonding material is selected which weakens at a temperature that, while high, is low enough to avoid damage to the assembled package, including avoiding inducing warping. In some implementations, a bonding material that begins to weaken or break down when raised to a temperature at or above 190°C may be used.

Alternatively, another form of temperature treatment may be used for carrier removal according to some implementations of the subject matter of this disclosure. In this alternative temperature treatment, the substrate stack and rigid carrier are cooled until the bonding material between the carrier and the base substrate weakens. Once the bonding material has weakened, the carrier may be removed by physically translating the carrier relative to the substrate stack. For implementations in which this cooling treatment is used, a bonding material is selected which weakens at a temperature that, while low, is high enough to avoid damage to the assembled package, including avoiding inducing warping.

If the location joint between the carrier and the base substrate allows exposure to a laser, then in yet another method according to implementations of the subject matter of this disclosure, laser exposure may be used to release the rigid carrier from the base substrate. For example, a suitable laser may be a middle-wave to long-wave ultraviolet laser with a wavelength between 248 nm and 355 nm. Such a method may be used with a rigid carrier material, such as glass, which is transmissive in the wavelength of the laser in order to allow the laser to transmit through the carrier. Alternatively, this method may be used with a carrier that is opaque to the laser wavelength, as long as the joint can be exposed (e.g., at an edge) to the laser. This method also employs a release material that interacts with the adhesive bonding material to facilitate the weakening of the adhesive bonding material. The laser may release the bonding material (as altered by the release material) by thermal action (in which case the bonding material should be chosen according to criteria discussed above), or by breaking down chemical bonds in the bonding material (e.g., by ablation). Even in the case of thermal action, the carrier removal temperature from laser exposure should not result in base substrate warping and may be a low stress carrier removal option.

Various organic bonding materials are available that may be used to adhere the base substrate to the carrier while allowing removal of the carrier by one of the foregoing removal techniques. For example, suitable organic bonding materials are available from Brewer Science, Inc., of Rolla, Missouri under the trademarks WaferBOND® HT-10.11, WaferBOND® HT-10.12, and BrewerBOND® 305. While each of these bonding materials may be suitable for mechanical shear or torque removal techniques, the WaferBOND® HT-10.11 material is particularly well suited for temperature-based or chemical-based removal techniques when the base substrate has a thickness less than 75 microns, while the WaferBOND® HT-10.12 material is particularly well-suited for temperature-based or chemical-based removal techniques when the base substrate has a thickness greater than or equal to 75 microns. On the other hand, the BrewerBOND® 305 material is particularly well-suited for laser-based or mechanical (shear or torque) removal techniques.

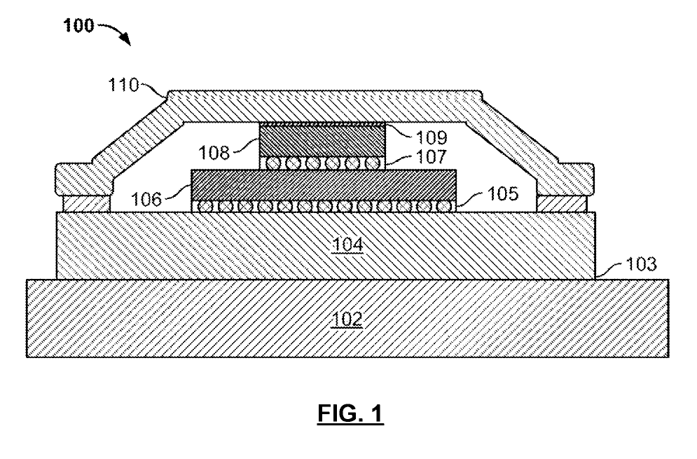

FIG. 1 illustrates the different layers of a substrate stack 100 which is attached to a rigid carrier 102 during fabrication. A base substrate 104 is adhered to the carrier 102 using a bonding material 103. In some implementations of the present disclosure, the base substrate is formed of a plurality of laminated dielectric layers, for instance a plurality of high-density interconnections (HDI) layers. A build-up substrate 106 is mounted above base substrate 104 in the shown orientation, bonded by an underfill material 105. An IC die 108 including one or more ICs may be mounted above and electrically coupled to the build-up substrate 106 using another underfill bonding agent 107. The IC die 108 may be mounted in the shown orientation. Optionally, depending on the intended end use of the stacked substrate package 100, a thermal interface material (TIM) 109 may be applied on a top surface of the IC die 108. TIM 109 may be used for better heat dissipation from the heat-producing IC die 108. As further option, a lid 110 may enclose the IC die 108, in which case TIM 109 conducts heat to the lid 110, which acts as a heat sink and helps protect the IC die 108 from damage caused by mechanical handling. The lid 110 also provides mechanical stiffness to help resist warping of the assembled stacked substrate package 100.

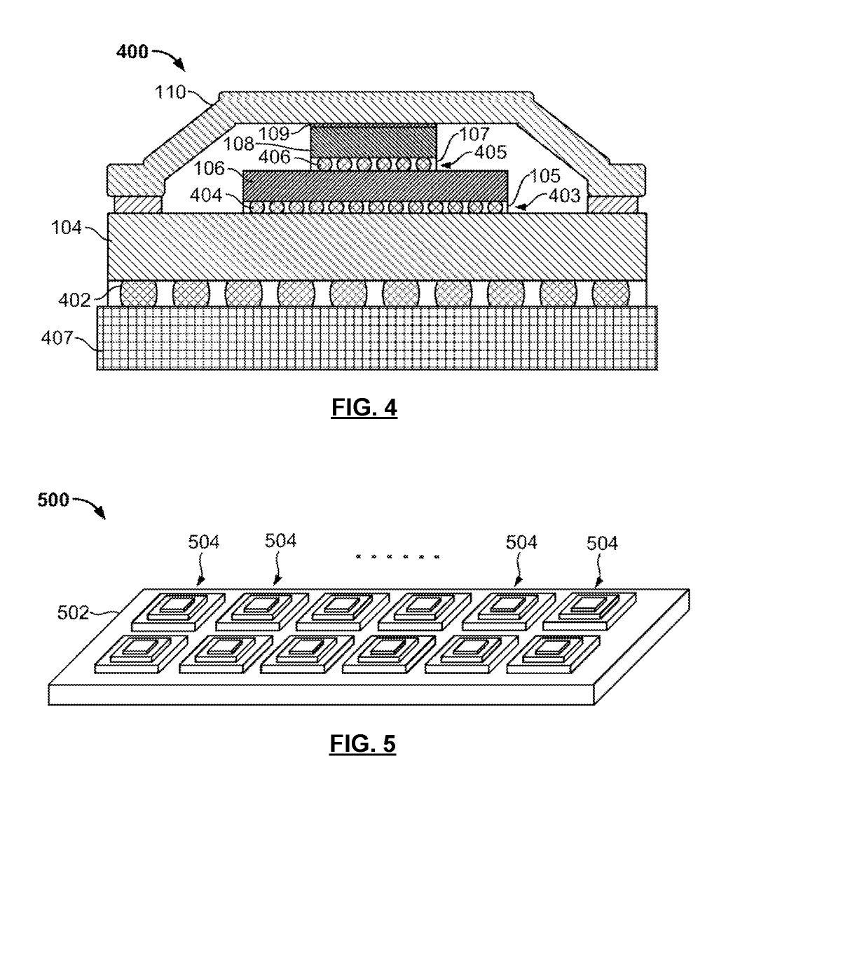

Issues may arise during the assembly of stacked substrate package 100 if any of the layers warp, such that the package input and output (I/O) contacts and surface-mounted contacts (e.g., contacts 402, 404, 406; see FIG. 4) on adjacent surfaces cannot make a connection. This warping can cause, for example, an open circuit. The stated warping may occur during the assembly process when the layers are being bonded and electrically coupled together. Underfill bonding materials 105, 107 are distributed at the interface between base substrate 104 and build-up substrate 106 and the interface between build-up substrate 106 and IC die 108. The underfill bonding materials 105, 107 are cured until the underfill bonding materials 105, 107 secure the layers together and allow the surface-mounted contacts 404, 406 on the adjacent surfaces to make proper contact. These layers may warp as the underfilling bonding materials 105, 107 cure because, for example, each layer may have a different CTE, which may cause the different layers to expand or contact at different rates when exposed to a change in temperature. However, the rigid carrier 102 can serve not only as a rigid surface on which to assemble substrate stack 100 to prevent warping but also may be selected to have a coefficient of thermal expansion that is substantially equal to that of the base substrate 104. Matching the CTE between the carrier 102 and the base substrate 104 further aids in preventing warping during the binding and curing of the two layers.

The interface between the carrier 102 and the base substrate 104 is joined by a bonding material 103. A release material may also be used at the interface as described above. The method selected for removal of carrier 102 may also include determining the selection of bonding material 103 and whether a release material is used in bonding of the carrier 102 and the base substrate 104.

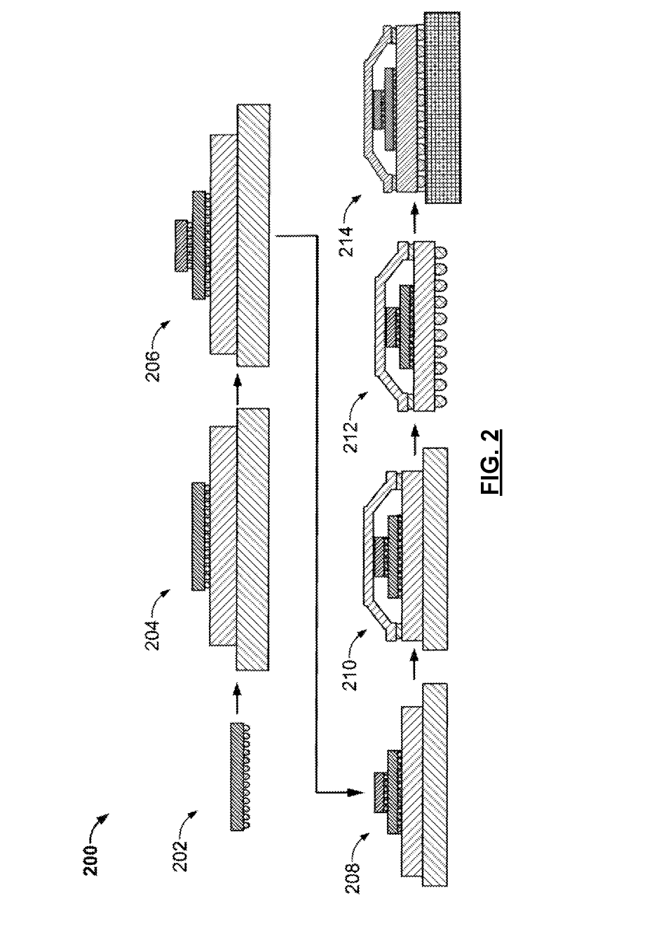

Example assembly methods for the substrate stack 100 are illustrated and described with respect to FIGS. 2-10. In the assembly example 200 shown in FIG. 2, the build-up substrate 106 is mounted onto base substrate 104 and the base substrate 104 is adhered to the carrier 102 at 204. The build-up substrate 106 is electrically coupled to the base substrate at 204. The IC die 108 is then mounted and electrically coupled to the build-up substrate 106 at 206. This takes advantage of the rigidity of the carrier 102 when mounting the build-up substrate 106 and when mounting the IC die 108.

To take advantage of the rigidity of the carrier 102, the build-up substrate 106 is bonded to the base substrate 104 and the IC die 108 is bonded to the build-up substrate at 208. This is done by depositing an underfill bonding material 105, 107 at the build-up substrate-base substrate interface 403 (see FIG. 4) and the IC die-build-up substrate interface 405 (see FIG. 4). In an embodiment, after the underfill bonding materials 105, 107 are cured, the surface-mounted contacts 404, 406 at the build-up substrate-base substrate interface 403 and the IC die-build-up substrate interface 405 are aligned and bonded. Optionally, at 210, a TIM 109 is applied, and the substrate stack 100 is enclosed with a lid 110. The lid 110 is in thermal contact with TIM 109. After assembly is complete, in order to provide a usable stacked substrate package, carrier 102 is removed, and at 212 package I/O contacts 402 are formed on the bottom surface of the base substrate 104. In an embodiment, and as part of further processing, the assembled stacked substrate package is mounted and electrically coupled to a board 407 (see FIG. 4) at 214, such as a printed circuit board (PCB) for various applications.

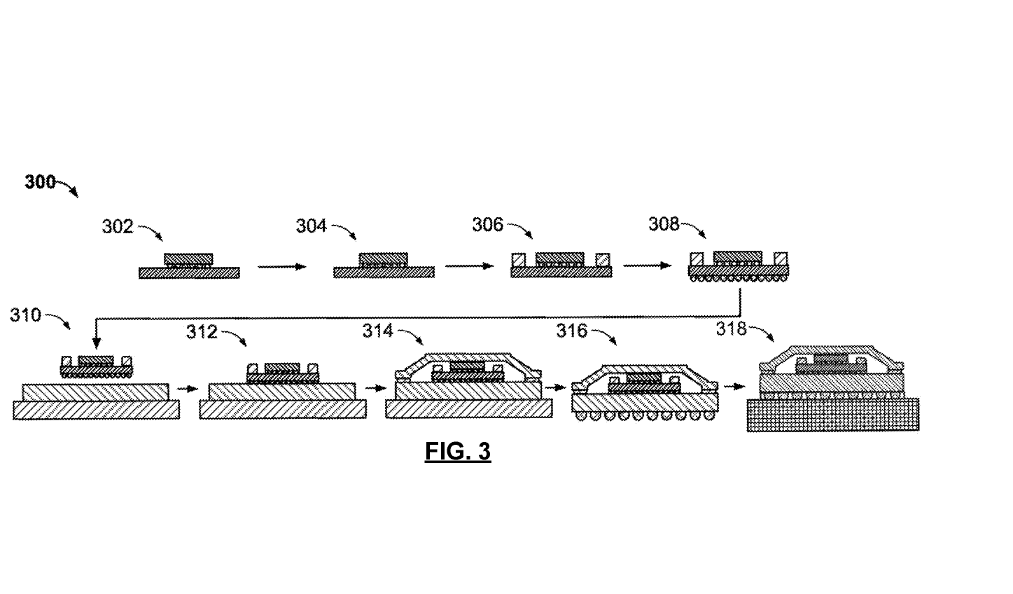

Another assembly example 300 is shown in FIG. 3, which begins with mounting, at 302 and coupling, at 304, the IC die 108 to the build-up substrate 106, such that the surface-mounted contacts 406 are connected without any open circuits. This is followed at 308 by forming surface-mounted contacts 404 on the bottom surface of the build-up substrate 106. At 310, the base substrate 104 is then adhered to the carrier 102, followed at 312 by the mounting and underfill bonding of the build-up substrate to the base substrate 104. Optionally, at 314, the TIM 109 may be applied and the IC die 108 may be enclosed with the lid 110. At 316, the carrier 102 is removed and package I/O contacts 402 are formed on the bottom surface, in the orientation shown in FIGS. 3-4, of the base substrate 104. Once the package I/O contacts 402 are attached, the assembled stacked substrate package may be placed onto and electrically coupled to a circuit board 407 (see FIG. 4) at 318, such as a PCB.

FIG. 4 shows a resulting stacked substrate package 400 with the carrier 102 removed, according to some implementations of the subject matter of this disclosure. Each layer of the stacked substrate package 400 has surface-mounted contacts, arranged to align with, and coupled to, circuitry on an adjacent layer. The IC die 108 has surface-mounted contacts 406 that couple to the build-up substrate 106 at the IC die-build-up substrate interface 405. In addition, the build-up substrate 106 has surface-mounted contacts 404 that couple to the base substrate 104 at the build-up substrate-base substrate interface 403. The surface-mounted contacts 406 on the IC die 108 may be controlled collapse of chip connection (C4) bumps, micro-bumps, or copper pillar interconnects. As seen in FIG. 4, after the carrier 102 is no longer attached to the base substrate 104, package I/O contacts 402 are attached on the surface of the base substrate 104, allowing the stacked substrate package to be coupled electrically to a board 407 (e.g., to a PCB). The package I/O contacts 402 may be ball grid array (BGA) contacts. However, in other implementations of the stacked substrate package 400, other types of package I/O contacts may be used (e.g., a land grid array (LGA), a pin grid array (PGA), etc.).

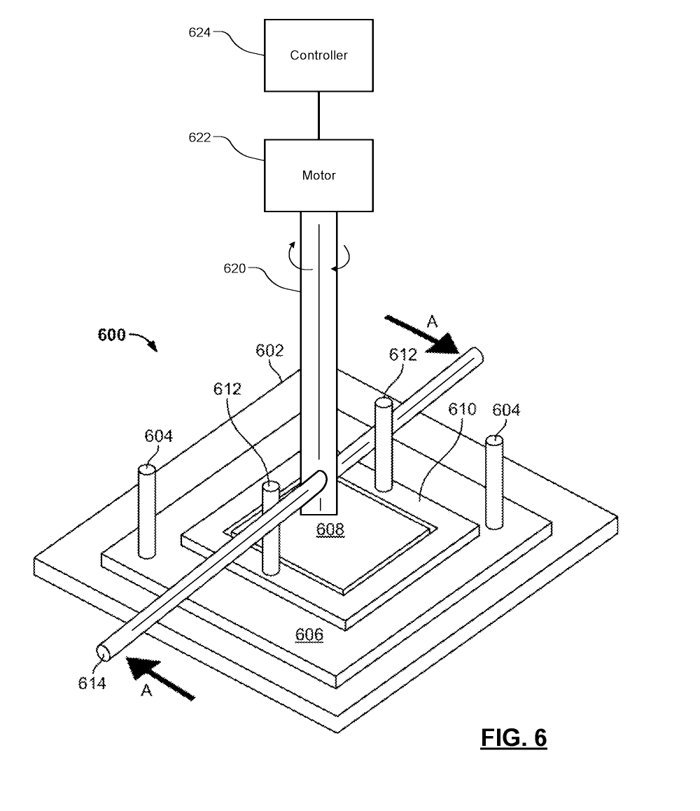

FIG. 5 shows a plurality of substrate stacks 504 mounted on top of a rigid carrier 502. This illustrates how the stacked substrate package assembly process may be done in parallel to increase the production output rate. Each of the plurality of substrate stacks 504 are built up with a base substrate, a build-up substrate, and at least one IC die. Although some example implementations of the subject matter of this disclosure includes a single substrate stack, multiple individual stacks 504 may be bonded to a single carrier and processed simultaneously.

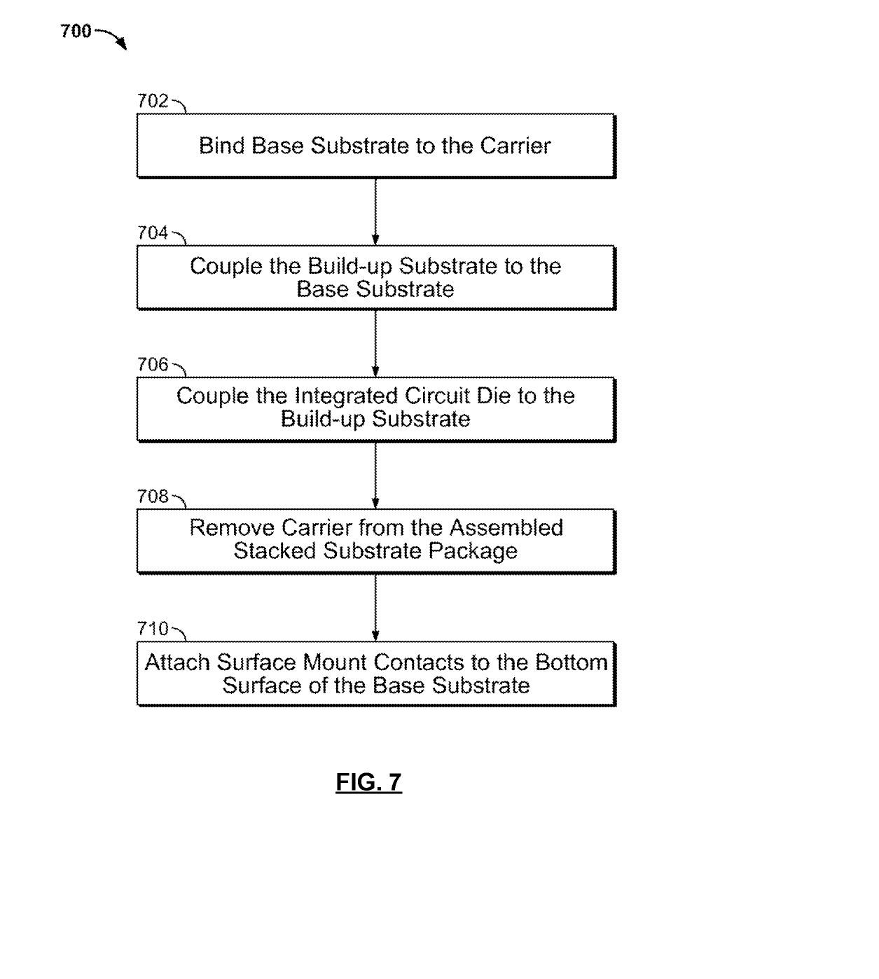

The mechanical torque method apparatus is seen in FIG. 6, where the base 602 is attached to two carrier secure pins 604 that extend in a direction perpendicular to the major plane of base 602. The carrier secure pins 604 are positioned to engage with two matching openings in carrier 606 in order to prevent movement in a plane parallel to the major plane of the base 602. The carrier 606, placed on the apparatus 600, has a substrate stack 608 assembled on top of the carrier 606. Apparatus 500 also includes a frame-shaped torque fixture 610, that has a major plane, where the frame-shaped torque fixture 610 is attached to two torque lever pins 612, which extend in a direction perpendicular to the major plane of the frame-shaped torque fixture 610. The frame-shaped torque fixture 610 is positioned around the perimeter of the substrate stack 608. The torque lever pins 612 are used as points of contact for the torque rod 614, to exert forces on torque lever pins 612 in, for example, the direction of arrows A, resulting in a torque about an axis perpendicular to the major plane of frame-shaped torque fixture 610. This torque is transferred to the substrate stack 608 relative to the carrier 606, which is held in place by carrier secure pins 604, to separate the carrier 606 from substrate stack 608.

In an example embodiment, the torque rod 614 is connected to a shaft 620, which is connected to a motor 622. A controller 624 controls operation of the motor 622 including rotation of the torque rod 614. The controller 624 determines when to rotate the torque rod 614 and the rate at which to rotate the torque rod 614 relative to the carrier 606. After the substrate stack 608 has been formed, the controller 624 rotates the torque rod 614 at a selected speed and/or according to a selected speed versus time profile to release the substrate stack 608 from the carrier 606.

A method 700 in accordance with implementations of the subject matter of this disclosure is diagrammed in FIG. 7. The method 700 begins at 702, where the base substrate is bound to the carrier, in order to prevent warping of the base substrate. At 704, the build-up substrate is then bonded to the base substrate. At 706, the IC die is bonded to the build-up substrate 706. After all layers are assembled and thus stacked, at 708 the carrier is removed from the assembled substrate stack. At 710, the surface-mounted contacts 402 are formed on the surface of the base substrate 710.

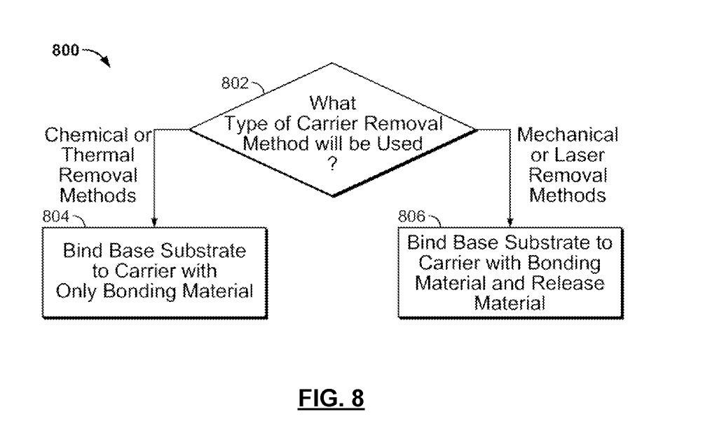

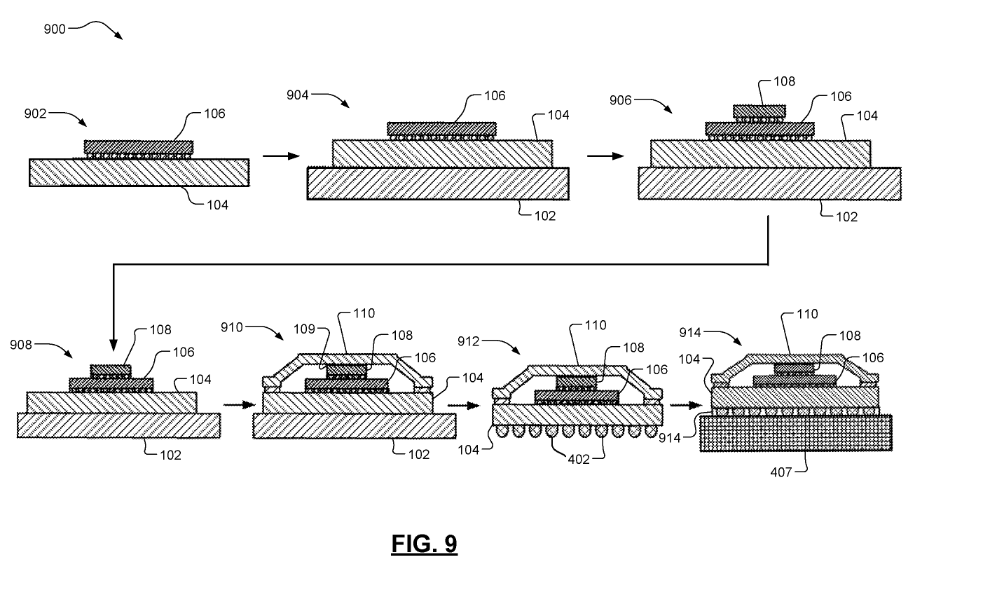

FIG. 8 shows a flow diagram illustrating further details of implementation of the binding of the base substrate to the rigid carrier at 702. At 802, a determination is made of the type of carrier removal method to be used at 708. If a chemical solvent or thermal treatment carrier removal methods are used, then at 804 only a bonding material is used to bind the base substrate to the carrier. If at 802 it is determined that the carrier is to be removed by laser exposure, or by mechanical shear or torque, then at 806 a release material is used in conjunction with the bonding material.

Thus, it is seen that the assembly of a stacked substrate package in a manner that avoids warped package layers, which may cause misalignment of surface-mounted contacts between layers, has been provided.

In the implementation example 900 shown in FIG. 9, the build-up substrate 106 is mounted and electrically coupled to the base (or HDI) substrate 104, as shown at 902. At 904, the base substrate 104, including the build-up substrate 106, is mounted to the rigid carrier 102. In an example embodiment, the base substrate 104 is adhered to the carrier 102. At 906, the IC die 108 is then mounted and electrically coupled to the build-up substrate 106.

At 908 and to take advantage of the rigidity of the carrier 102, the build-up substrate 106 is bonded to the base substrate 104 and the IC die 108 is bonded to the build-up substrate 106. This includes depositing an underfill bonding material designated 105, 107 in FIG. 1 at the build-up substrate-base substrate interface 403 (see FIG. 4) and at the IC die-build-up substrate interface 405 (see FIG. 4). After the underfill bonding materials 105, 107 are cured, i) the surface-mounted contacts 404 at the build-up substrate-base substrate interface 403 are horizontally aligned with the build-up substrate 106 and bonded, and ii) the surface-mounted contacts 406 at the IC die-build-up substrate interface 405 are horizontally aligned with the IC die 108 and bonded.

Optionally, at 910, the TIM 109 may be applied, and the build-up substrate 106 and IC die 108 may be enclosed with the lid 110, which is in contact with the TIM 109. After assembly is complete, in order to provide a usable stacked substrate package, the carrier 102 is removed. At 912, the package I/O contacts 402 are formed on the bottom surface of the base substrate 104. At 914, the assembled stacked substrate package may be mounted and electrically coupled to the board 407 and underfill bonding material 914 may be added between the package I/O contacts 402. The assembled stacked substrate package includes the IC die 108, the build-up substrate 106, the base substrate 104, and the lid 110. The package is mounted on and electrically coupled to the board 407 via the package I/O contacts 402.

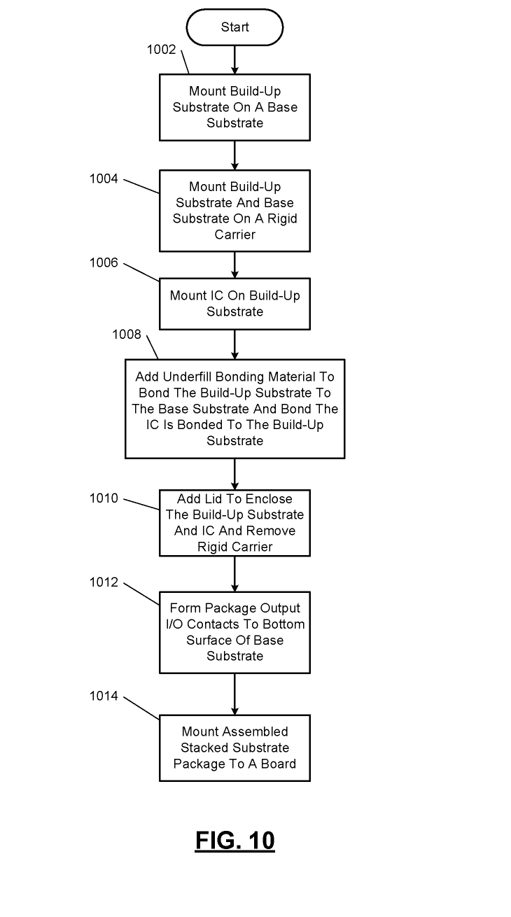

FIG. 10 shows another example assembly method 1000 for a stacked substrate package which is consistent with the assembly process described with respect to FIG. 9. The method 1000 begins at 1002, where the build-up substrate 106 is mounted to the base substrate 104.

At 1004, the build-up substrate 106 and base substrate 104 are mounted to the rigid carrier 102. In an example embodiment, the base substrate 104 is adhered to the carrier 102. At 1006, the IC die 108 is then mounted to the build-up substrate 106.

At 1008 and to take advantage of the rigidity of the carrier 102, the build-up substrate 106 is electrically coupled and bonded to the base substrate 104 and the IC die 108 is electrically coupled and bonded to the build-up substrate 106. In an embodiment, this includes depositing an underfill bonding material designated 105, 107 in FIG. 1 at the build-up substrate-base substrate interface 403 (see FIG. 4) and at the IC die-build-up substrate interface 405 (see FIG. 4). After the underfill bonding materials 105, 107 are cured, i) the surface-mounted contacts 404 at the build-up substrate-base substrate interface 403 are horizontally aligned with the build-up substrate 106 and bonded, and ii) the surface-mounted contacts 406 at the IC die-build-up substrate interface 405 are horizontally aligned with the IC die 108 and bonded.

At 1010, the TIM 109 is applied, and build-up substrate 106 and IC die 108 are enclosed with the lid 110, which is in contact with TIM 109 on the IC die 108 and on the base substrate 104. After assembly is complete, in order to provide a usable stacked substrate package, the carrier 102 is removed. Depending on the selected one of the carrier methods disclosed herein that is used to remove the rigid carrier 102, the apparatus (or system) of FIG. 6 may be used to perform the removal of the carrier 102.

At 1012, the package I/O contacts 402 are formed on the bottom surface of the base substrate 104.

At 1014, the assembled stacked substrate package may be mounted and electrically coupled to the board 407 and underfill bonding material 914 may be added between the package I/O contacts 402.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital IC; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

In this application, apparatus elements described as having particular attributes or performing particular operations are specifically configured to have those particular attributes and perform those particular operations. Specifically, a description of an element to perform an action means that the element is configured to perform the action. The configuration of an element may include programming of the element, such as by encoding instructions on a non-transitory, tangible computer-readable medium associated with the element.

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A method for assembling and mounting a stacked substrate package, the method comprising:
a) mounting a build-up substrate to a base substrate, the build-up substrate comprising interconnections between surfaces of the build-up substrate, and the base substrate comprising interconnections between surfaces of the base substrate;
b) mounting the base substrate to a rigid carrier; and
c) mounting an integrated circuit to the build-up substrate,
wherein, during a), b), and c), the build-up substrate, the base substrate and the integrated circuit are stacked to provide a substrate stack, and
wherein
i) a) is performed before at least one of b) and c),
ii) c) is performed before at least one of a) and b), or
iii) b) is performed before a) and c), and c) is performed before a).

2. The method of claim 1, wherein a) is performed before b).

3. The method of claim 1, wherein a) is performed before c).

4. The method of claim 1, wherein a) is performed before b) and c).

5. The method of claim 1, wherein a) and c) are performed concurrently.

6. The method of claim 1, wherein c) is performed before a).

7. The method of claim 1, wherein c) is performed before b).

8. The method of claim 1, wherein c) is performed before a) and b).

9. The method of claim 1, wherein d) is performed after at least one of a), b) and c).

10. The method of claim 1, further comprising d) binding layers of the base substrate together, wherein d) is performed before at least one of a), b), and c).

11. The method of claim 10, wherein d) is performed before a) and c).

12. The method of claim 1, further comprising mounting a lid over the integrated circuit and to the base substrate.

13. The method of claim 1, wherein the rigid carrier has a same coefficient of thermal expansion as the base substrate.

14. The method of claim 1, wherein:
a first plurality of contacts electrically connect the integrated circuit to the build-up substrate; and
a second plurality of contacts electrically connect the build-up substrate to the base substrate.

15. The method of claim 14, further comprising underfilling space between the integrated circuit and the build-up substrate and space between the build-up substrate and the base substrate with bonding material.

16. The method of claim 15, wherein the space between the integrated circuit and the build-up substrate and the space between the build-up substrate and the base substrate are underfilled subsequent to performing a), b), and c).

17. The method of claim 14, wherein the first plurality of contacts and the second plurality of contacts are implemented as at least one of i) a ball grid array, ii) controlled collapse of chip connections, iii) micro-bumps, iv) copper pillar connections, v) a land grid array, vi) a pin grid array.

18. The method of claim 1, further comprising:
d) releasing the substrate stack from the rigid carrier; and
subsequent to d), forming contacts on one of the surfaces of the base substrate and mounting the base substrate to a board such that the contacts electrically connect the base substrate to the board.

19. The method of claim 1, wherein the base substrate is adhered to the rigid carrier.

20. The method of claim 1, further comprising d) releasing the substrate stack from the rigid carrier, where d) comprises treating an adhesive that adheres the base substrate to the rigid carrier with a solvent to weaken the adhesive and physically separate the base substrate from the rigid carrier.

21. The method of claim 1, further comprising:
disposing a fixture on the rigid carrier, the fixture configured to surround the base substrate and comprising a first plurality of pins extending perpendicular to a top surface of the fixture; and
releasing the substrate stack from the rigid carrier including positioning a torque rod between the first plurality of pins and applying torque on the fixture via the first plurality of pins relative to the rigid carrier to release the base substrate from the rigid carrier.

22. A method for assembling and mounting a stacked substrate package, the method comprising:
a) mounting a build-up substrate to a base substrate, the build-up substrate comprising interconnections between surfaces of the build-up substrate, and the base substrate comprising interconnections between surfaces of the base substrate;
b) mounting the base substrate to a rigid carrier; and
c) mounting an integrated circuit to the build-up substrate,
wherein
during a), b), and c), the build-up substrate, the base substrate and the integrated circuit are stacked to provide a substrate stack, and
either
ii) b) is performed before a) and c), and c) is performed before a).

23. The method of claim 22, further comprising releasing the substrate stack from the rigid carrier.
